(19) United States
(12) Patent Application Publication
(10) Pub. No.: US 2026/0338870 A1
(43) Pub. Date: Oct. 29, 2026

(54) BATTERY DIAGNOSTIC DEVICE AND METHOD

(71) Applicant: LG ENERGY SOLUTION, LTD., Seoul (KR)

(72) Inventor: Jeong Wan KIM, Daejeon (KR)

(21) Appl. No.: 19/123,377

(22) PCT Filed: Sep. 15, 2023
(86) PCT No.: PCT/KR2023/013973

§ 371 Date: Apr. 22, 2025

(30) Foreign Application Priority Data
Nov. 7, 2022 (KR) 10-2022-0147410

(51) Int. Cl. G01R 31/392; G01R 31/389; G01R 31/396

(52) U.S. Cl. CPC G01R 31/392; G01R 31/389; G01R 31/396

(57) ABSTRACT

The present disclosure relates to a battery diagnostic device and method. In some embodiments, the battery diagnostic device may include: a measurement unit which measures cell impedances of a plurality of battery cells, a fixed impedance of at least one component, and a first module impedance of a battery module; and a control unit which determines an assembly state of the battery module based on the cell impedance, the fixed impedance, and the first module impedance.

### CROSS-REFERENCE TO RELATED APPLICATIONS

This application is a National Phase entry pursuant to 35 U.S.C. 371 of International Application No. PCT/KR2023/013973 filed on Sep. 15, 2023, which claims the benefit of Korean Patent Application No. 10-2022-0147410 filed on Nov. 7, 2022 in the Korean Intellectual Property Office. The contents of the above-identified applications are incorporated by reference herein in their entireties.

### TECHNICAL FIELD

The present disclosure relates to a diagnostic device and diagnostic method for a battery, and more particularly, to a battery diagnostic device and method capable of diagnosing an assembly state.

### BACKGROUND

Recently, as the demand for portable electronic products such as laptops, video cameras, and portable phones has increased rapidly, and the development of electric vehicles, energy storage batteries, robots, and satellites has begun in earnest, much research is being conducted on secondary batteries used as driving power sources therefor.

A battery module may be formed by electrically connecting a plurality of battery cells. If a plurality of battery cells in a battery module are not properly connected due to poor assembly, the performance and stability of the battery module may deteriorate.

Therefore, recently, there has been a demand for a way for diagnosing a battery module to determine whether there is an assembly abnormality of the battery module.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

Embodiments of the present disclosure may provide a battery diagnostic device and method capable of diagnosing an assembly state.

The technical aspects of the present disclosure are not limited to the technical aspects mentioned above, and other technical aspects not mentioned will be clearly understood by those skilled in the art from the description below.

A diagnostic device for inspecting an assembly state of a battery module including at least one component and a plurality of battery cells according to an embodiment may include: a measurement unit which measures cell impedances of the plurality of battery cells, a fixed impedance of the at least one component, and a first module impedance of the battery module; and a control unit which determines an assembly state of the battery module based on the cell impedances, the fixed impedance, and the first module impedance.

According to an embodiment, the control unit may calculate a second module impedance by determining a sum of the cell impedances and adding the fixed impedance to the sum, and compare the first module impedance and the second module impedance to determine an assembly state of the battery module.

According to an embodiment, the control unit may determine the assembly state of the battery module is acceptable if a difference between the first module impedance and the second module impedance is within a threshold, and determine the assembly state of the battery module is defective if the difference between the first module impedance and the second module impedance exceeds the threshold.

According to an embodiment, the measurement unit may include: a cell measurement unit which measures the respective cell impedances for the plurality of battery cells; and a module measurement unit which measures the first module impedance of the battery module.

According to an embodiment, the module measurement unit may have a higher measurable voltage range than the cell measurement unit.

According to an embodiment, the module measurement unit may have the same measurable voltage range as the cell measurement unit.

According to an embodiment, the diagnostic device may further include a voltage distribution circuit which electrically connects the module measurement unit and the battery module and which includes a plurality of resistors.

According to an embodiment, the voltage distribution circuit may distribute a voltage input from the battery module according to a resistance ratio of the plurality of resistors and supply a generated module voltage to the module measurement unit.

According to an embodiment, the diagnostic device may further include a memory in which the fixed impedance is stored, wherein the first module impedance and the cell impedances may change based on variations in a frequency, and the fixed impedance may have a fixed value that does not change based on the variations in the frequency.

According to an embodiment, the cell measurement unit may initially charge and activate the plurality of battery cells, and subsequently measure the cell impedances at a first time point after a first time period has elapsed, and the module measurement unit, after the activation, may measure the first module impedance at a second time point after a second time period has elapsed.

According to an embodiment, the cell measurement unit may measure a direct current internal resistance (DCIR) of the plurality of battery modules, and subsequently measure the cell impedances at a first time point after a first time period has elapsed, and the module measurement unit, after measuring the direct current internal resistance (DCIR), may measure the first module impedance at a second time point after a second time period has elapsed.

According to an embodiment, the first time period may be the same period as the second time period.

A diagnostic method for diagnosing an assembly state of a battery module including at least one component and a plurality of battery cells according to an embodiment may include: measuring cell impedances of the plurality of battery cells, a fixed impedance of the at least one component, and a first module impedance of the battery module; and determining an assembly state of the battery module based on the cell impedances, the fixed impedance, and the first module impedance.

According to an embodiment of the present disclosure, an assembly state of a battery module may be determined based on cell impedances of a plurality of battery cells, a fixed impedance of at least one component, and a first module impedance of the battery module. Accordingly, it is possible to determine whether there is a defect in the assembly of a battery cell or a defect in the assembly of a battery module, and thus to take appropriate measures, thereby improving safety.

In addition, various effects that are directly or indirectly identified through this document may be provided.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawings.

FIG. 1 is a block diagram showing a diagnostic device of a battery according to a first embodiment.

FIG. 2 is a block diagram showing another example of a measurement unit shown in FIG. 1.

FIG. 3 is a graph showing a cell impedance measured through a cell measurement unit shown in FIG. 1.

FIG. 4 is a graph showing a first module impedance measured through a module measurement unit shown in FIG. 1.

FIG. 5 is a flowchart showing a battery diagnosis method according to a first embodiment.

FIG. 6 is a block diagram showing a diagnostic device of a battery according to a second embodiment.

### DETAILED DESCRIPTION

Hereinafter, with reference to the accompanying drawings, preferred embodiments will be described in detail so that those skilled in the art can easily implement aspects of the present disclosure. However, these aspects may be implemented in various different forms and is not limited or restricted by the following embodiments.

In order to clearly explain certain aspects, detailed descriptions of parts unrelated to the description or related known technologies that may unnecessarily obscure the gist of these aspects have been omitted, and in adding reference numerals to components in each drawing in this specification, identical or similar reference numerals are used for identical or similar components throughout the specification.

In addition, terms and words used in this specification and claims should not be construed as limited to their usual or dictionary meanings, but should be interpreted as meanings and concepts consistent with the technical idea of the present disclosure on the basis of the principle that an inventor can appropriately define the concept of a term in order to explain concepts in the best way possible.

### Diagnostic Device According to First Embodiment

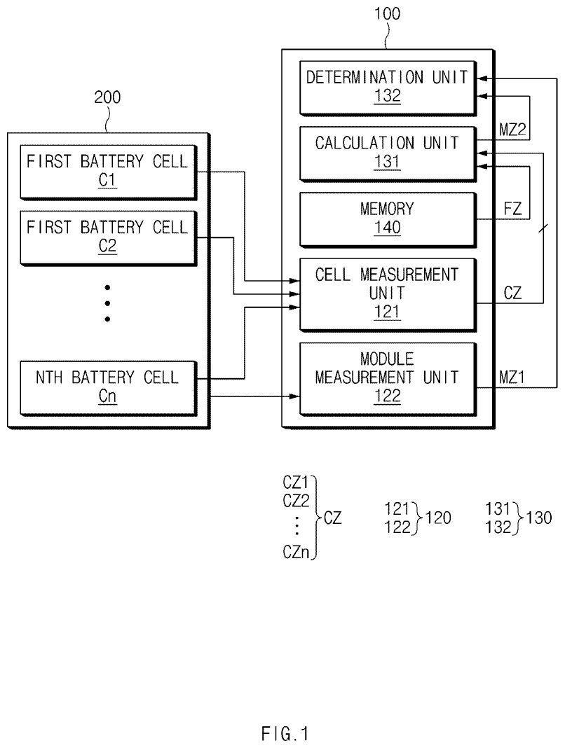

FIG. 1 is a block diagram showing a diagnostic device of a battery according to a first embodiment.

Referring to FIG. 1, a diagnostic device 100 may diagnose an assembly state of a battery module 200 after an assembly process of the battery module 200.

The battery module 200 may include a plurality of battery cells C1, C2, . . . , Cn and at least one component. Each of the plurality of battery cells C1, C2, . . . , Cn has a negative terminal and a positive terminal and refers to an independent physically separable cell. The plurality of battery cells C1, C2, . . . , Cn included in the battery module 200 may be connected in series and/or parallel.

The diagnostic device 100 may measure impedances of each of the battery cells C1, C2, . . . , Cn and the battery module 200 and detect assembly defects in the battery module on the basis of the measured impedances. The diagnostic device 100 may supply an electrical signal to the assembled battery module 200, and then, after a predetermined time has elapsed, measure impedances of each of the battery cells C1, C2, . . . , Cn and the battery module 200. As an example, the diagnostic device 100 may measure impedances of each of the battery cells C1, C2, . . . , Cn and the battery module 200 after initially charging and activating the battery module 200. As another example, the diagnostic device 100 may measure a direct current internal resistance (DCIR) of a plurality of battery modules 20 and then measure impedances of each of the battery cells C1, C2, . . . , Cn and the battery module 200.

According to an embodiment, the diagnostic device 100 may include a measurement unit 120, a control unit 130, and a memory 140.

The measurement unit 120 may include a cell measurement unit 121 and a module measurement unit 122 to measure impedances CZ, MZ1 inside the battery module 200. For example, the measurement unit 120 may measure impedances CZ, MZ1 by using electrochemical impedance spectroscopy (EIS).

The cell measurement unit 121 may be configured to measure a cell impedance CZ of each of the plurality of battery cells C1, C2, . . . , Cn. The cell measurement unit 121 may be configured to apply an alternating current voltage to each of the plurality of battery cells C1, C2, . . . , Cn. The cell measurement unit 121 may be configured to apply alternating voltage to each of the plurality of battery cells C1, C2, . . . , Cn while changing a frequency. For example, the cell measurement unit 121 may be configured to charge each of the plurality of battery cells C1, C2, . . . , Cn while applying an alternating voltage to each of the plurality of battery cells C1, C2, . . . , Cn, and measure cell impedances CZ1, CZ2, . . . , CZn of each of the plurality of battery cells C1, C2, . . . , Cn during such a charging process.

The module measurement unit 122 may be configured to measure a first module impedance MZ1 of the battery module 200 including the plurality of battery cells C1, C2, . . . , Cn. The module measurement unit 122 may be configured to apply an alternating voltage to the battery module 200. The module measurement unit 122 may be configured to apply an alternating voltage to the battery module 200 while changing a frequency. For example, the module measurement unit 122 may be configured to charge the battery module 200 while applying an alternating voltage to the battery module 200, and measure a first module impedance MZ1 of the battery module 200 in such a charging process.

The module measurement unit 122 may have a higher measurable voltage range than the cell measurement unit 121. Since a module voltage of the battery module 200 input to the module measurement unit 122 is higher than a cell voltage of the battery cells C1, C2, . . . Cn input to the cell measurement unit 121, a measurable voltage range of the module measurement unit 122 may be set high. For example, the cell measurement unit 121 may measure a cell impedance, which is a low-voltage alternating current impedance of less than 5 V. The module measurement unit 122 may measure a first module impedance MZ1, which is a high-voltage alternating current impedance of 1000 V or less.

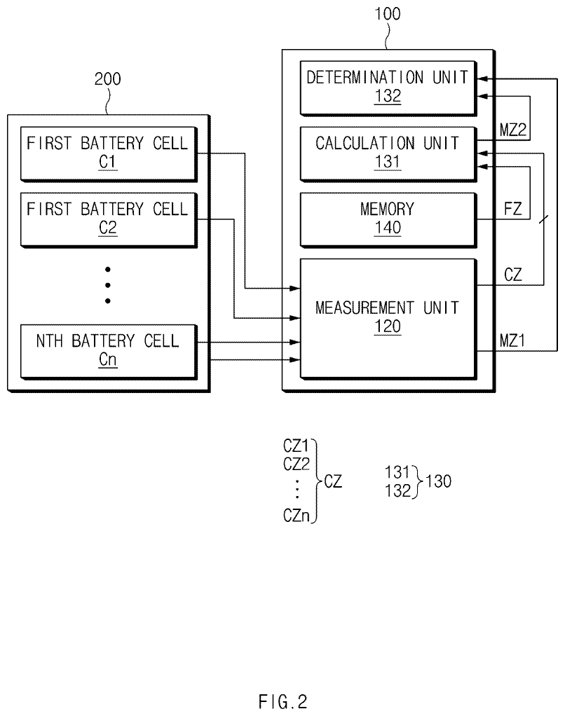

As an example, in the measurement unit 120, the cell measurement unit 121 and the module measurement unit 122 may be individually configured, as shown in FIG. 1. As another example, the measurement unit 120 may be composed as one including only a module measurement unit, omitting a cell measurement unit, as shown in FIG. 2. The measurement unit 120 shown in FIG. 2 may have a high measurable voltage range identically to the module measurement unit shown in FIG. 1. Accordingly, the measurement unit 120 shown in FIG. 2 may measure not only a first module impedance MZ1 but also a cell impedance CZ.

The memory 340 may store a fixed impedance FZ. The fixed impedance FZ may be an impedance of at least one component in the battery module 200 excluding the plurality of battery cells C1, C2, . . . , Cn. For example, a fixed impedance FZ may be calculated as the sum of impedances of all components in the battery module 200 excluding the plurality of battery cells C1, C2, . . . , Cn. The fixed impedance FZ may have a fixed value that does not vary with a frequency. The fixed impedance FZ may be a value obtained in advance through a prior measurement before measuring at least one of cell impedances CZ and a first module impedance MZ1.

The control unit 130 may determine an assembly state of the battery module 200 on the basis of cell impedances CZ, a first module impedance MZ1, and a fixed impedance FZ. The control unit 130 may be connected to the measurement unit 120 and the memory 140 to be able to communicate therewith in a wired manner and/or wirelessly.

The control unit 130 may include a calculation unit 131 and a determination unit 132. The calculation unit 131 and the determination unit 132 may be integrated into one component (e.g., a single chip) or may be implemented as a plurality of separate components (e.g., multiple chips).

The calculation unit 131 may receive cell impedances CZ from the cell measurement unit 121, a first module impedance MZ1 from the module measurement unit 122, and a fixed impedance FZ from the memory 140. The calculation unit 131 may calculate a second module impedance MZ2 on the basis of received impedances CZ, MZ1, FZ.

The calculation unit 131 may sum cell impedances CZ1, CZ2, . . . , CZn of the plurality of battery cells C1, C2, . . . , Cn, respectively, as shown in Equation 1, and calculate a second module impedance MZ2 by adding a fixed impedance FZ to a summed value.

$$MZ 2 = FZ + {\sum }_{i = 1}^{n} {CZ}_{i} \qquad [ Equation 1 ]$$

The determination unit 132 may detect assembly defects of the battery module 200 by comparing a calculated second module impedance MZ2 with a first module impedance MZ1 measured through the module measurement unit 122.

The determination unit 132 may compare a first module impedance MZ1 and a second module impedance MZ2 to determine if a difference between the first module impedance MZ1 and the second module impedance MZ2 is within a threshold (e.g., error range). If a difference between a first module impedance MZ1 and a second module impedance MZ2 is within a threshold, the determination unit 132 may determine that no assembly defect has occurred in the battery module 200 and determine the battery module 200 as a good product. When a difference between a first module impedance MZ1 and a second module impedance MZ2 exceeds a threshold, the determination unit 132 may determine that an assembly defect has occurred in the battery module 200 and determine that the battery module 200 is defective.

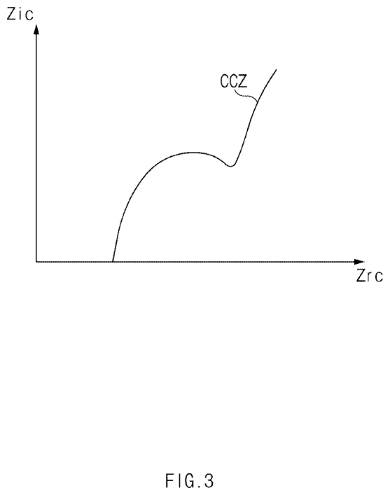

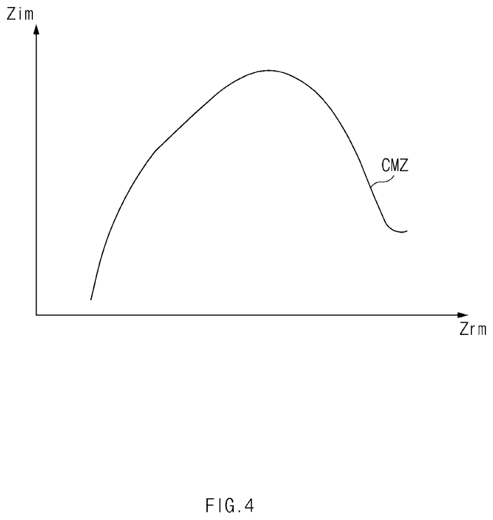

FIG. 3 is a graph showing a cell impedance measured through a cell measurement unit shown in FIG. 1, and FIG. 4 is a graph showing a first module impedance measured through a module measurement unit shown in FIG. 1. In FIG. 3, a horizontal axis may be said to be a real component Zrc of a cell impedance, and a vertical axis may be said to be an imaginary component Zic of a cell impedance. In FIG. 4, a horizontal axis may be said to be a real component Zrm of a first module impedance, and a vertical axis may be said to be an imaginary component Zim of a first module impedance. In FIGS. 3 and 4, the units of horizontal and vertical axes may be mΩ or Ω.

As shown in FIG. 3, a cell impedance may vary depending on a frequency of an alternating current signal applied to each of the plurality of battery cells C1, C2, . . . , Cn. As a frequency changes, a real component Zrc and an imaginary component Zic of a cell impedance change, and an intersection point thereof is displayed as an impedance point, which is a point on the coordinates, so as to derive a cell impedance curve CCZ. A cell impedance of each of the plurality of battery cells C1, C2, . . . , Cn may derive the cell impedance curve CCZ or cell impedance curves, at least one of which is different from the others.

The first module impedance may vary depending on a frequency of an alternating current signal applied to the battery module 200, as shown in FIG. 4. As a frequency changes, a real component Zrm and an imaginary component Zim of a first module impedance change, and an intersection point thereof is displayed as an impedance point, which is a point on the coordinates, so as to derive a first module impedance curve CMZ.

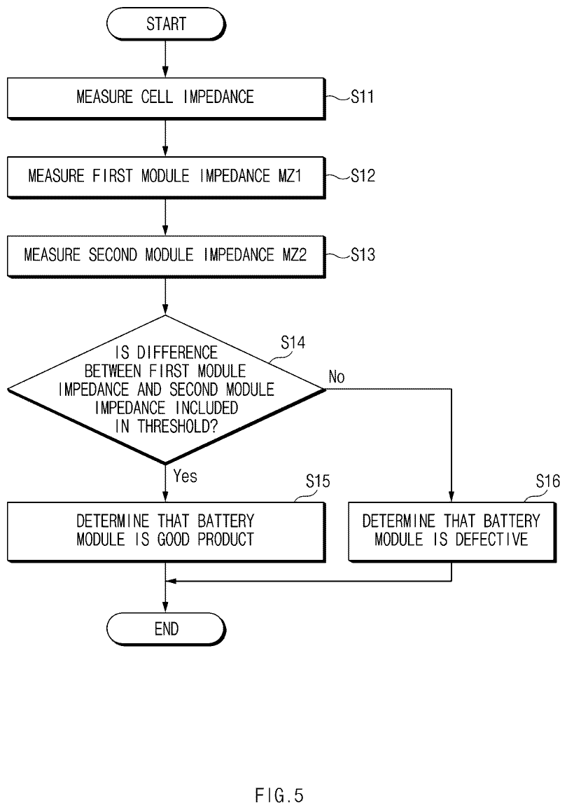

FIG. 5 is a flowchart showing a battery diagnosis method according to a first embodiment.

In operation S11, a cell measurement unit (e.g., cell measurement unit 121 in FIG. 1) may measure a cell impedance (e.g., cell impedance CZ in FIG. 1) of each of a plurality of battery cells (e.g., battery cells C1, C2, . . . , Cn in FIG. 1) within minutes. For example, the cell measurement unit may quickly measure cell impedances within 1 to 3 minutes by using an EIS measurement scheme. The measured cell impedances may be stored in a memory (e.g., memory 140 in FIG. 2) or transmitted to a control unit (e.g., control unit 130 in FIG. 1).

As an example, a cell impedance may be measured at a time point after a first predetermined period elapsed after activating each of the plurality of battery cells. Meanwhile, after a battery cell in a discharged state is assembled, the battery cell may be activated through primary charging.

As another example, a cell impedance may be measured at a time point after a first predetermined period elapsed after measuring a direct current internal resistance (DCIR) of each of the plurality of battery cells.

In operation S12, a module measurement unit (e.g., module measurement unit 122 in FIG. 1) may measure a first module impedance MZ1 of a battery module assembled to include at least one component and a plurality of battery cells within minutes. For example, the module measurement unit may quickly measure module impedances within 1 to 3 minutes by using an EIS measurement scheme. The measured module impedances may be transmitted to a control unit.

As an example, a first module impedance MZ1 may be measured at a time point after a second predetermined period elapsed after activating the battery module. The second period may be the same as the first period. Meanwhile, after a battery module in a discharged state is assembled, the battery module may be activated through initial charging.

As another example, a first module impedance MZ1 may be measured at a time point after a predetermined second period elapsed after measuring a direct current internal resistance (DCIR) of the battery module. The second period may be the same as the first period. The first period and the second period may be seconds to minutes. For example, the first period and the second period may be 30 seconds.

In operation S13, a control unit may calculate a second module impedance MZ2 by adding measured cell impedances and a fixed impedance stored in a memory. A fixed impedance may be an impedance of at least one component included in a battery module. At least one component may be a component other than a plurality of battery cells included in the battery module.

In operation S14, a control unit may compare a measured first module impedance MZ1 and a calculated second module impedance MZ2. The control unit may determine whether a difference between a measured first module impedance MZ1 and a calculated second module impedance MZ2 is included in a threshold.

In operation S15, if a difference between a first module impedance MZ1 and a second module impedance MZ2 is within a preset threshold as a result of comparison, a control unit may determine that there is no assembly defect in a battery module. Accordingly, the control unit may determine that the battery module is a good product.

In operation S16, if a difference between a first module impedance MZ1 and a second module impedance MZ2 is out of (or exceeds) a threshold as a result of comparison, a control unit may determine that there is an assembly defect in a battery module. Accordingly, a control unit may determine that the battery module is defective.

According to an embodiment, a cell impedance and a first module impedance MZ1 may be measured separately as described above. For example, a cell impedance may be measured after placing a plurality of battery cells. Then, after a battery module is formed by assembling a plurality of battery cells and at least one component, a first module impedance MZ1 may be measured.

According to an embodiment, a cell impedance and a first module impedance MZ1 may be measured simultaneously. A cell impedance and a first module impedance MZ1 may be measured after a battery module is formed by assembling a plurality of battery cells and at least one component.

### Diagnostic Device According to Second Embodiment

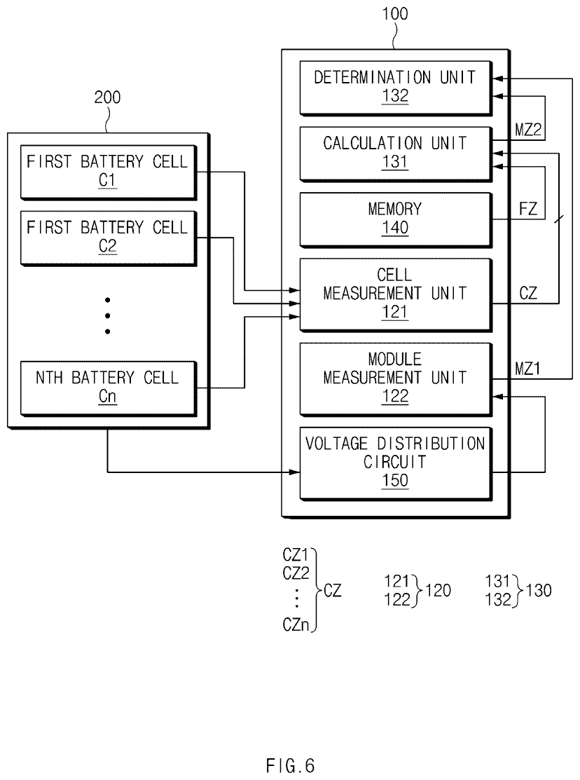

FIG. 6 is a block diagram showing a diagnostic device of a battery according to a second embodiment.

Referring to FIG. 6, the diagnostic device according to the second embodiment has the same components as the diagnostic device shown in FIG. 1, except that the former further includes a voltage distribution circuit 150. Accordingly, the previous description may apply to the same configuration and/or operation among configurations and/or operations of the diagnostic device described above.

A module measurement unit 122 may have a measurable voltage range that is the same or similar to that of a cell measurement unit 121. A measurable voltage range of the module measurement unit 122 may be the same or similar to cell voltages of a plurality of battery cells C1, C2, . . . , Cn. It is difficult to measure a module impedance of a battery module 200, which has a module voltage higher than a cell voltage of the battery cells C1, C2, . . . , Cn, through the module measurement unit 122. Accordingly, an adjusted voltage dropped through the voltage distribution circuit 150 connected to the front end of the module measurement unit 122 may be transmitted to the module measurement unit 122. Between the battery module 200 and the module measurement unit 122, the voltage distribution circuit 150 may be electrically connected thereto.

The voltage distribution circuit 150 may be formed to include a plurality of resistors and to have a resistance ratio that distributes a module voltage of the battery module 200. The voltage distribution circuit 150 may lower a module voltage to an adjustment voltage measurable by the module measurement unit 122 according to a resistance ratio of the plurality of resistors.

A resistance ratio of the plurality of resistors may be a value obtained in advance through a prior measurement before the diagnostic device is executed (before measuring a cell impedance). A resistance ratio may be set through a plurality of prior measurements so that a difference between the first module impedance (MZ1) and the second module impedance (MZ2) is included within a threshold. For example, a resistance ratio may be set so that a first module impedance MZ1 and a second module impedance MZ2 have the same value.

The module measurement unit 122 may measure a first module impedance by using an adjusted voltage dropped through a voltage distribution circuit. Even if am adjusted voltage dropped is input through a voltage distribution circuit, the module measurement unit 122 may recognize the voltage as a module voltage before a voltage drop and derive a first module impedance MZ1 corresponding to the module voltage.

The battery diagnostic device(s) according to the present disclosure described above may be applied to a battery pack. A battery pack, in addition to the above-described diagnostic device, may further include components typically included in a battery pack, such as one or more secondary batteries, a battery management system (BMS), a current sensor, a relay, a fuse, a pack case, and the like. A plurality of battery cells and a plurality of battery modules included in the battery pack may be targeted by the diagnostic device. At least some functions or operations of a control unit and a memory included in the diagnostic device may be implemented by a BMS.

The above-described battery pack may be applied to various devices. The battery pack may be applied to transportations such as electric bicycles, electric vehicles, and hybrids, but is not limited thereto and may be applied to various devices in which battery packs are usable.

The above-described diagnostic device and method are not limited to the embodiments described in each drawing, and may be implemented in various different forms. As an example, the diagnostic device may be applied to an inspection process before product shipment. As another example, the diagnostic device may be applied to an inspection process after product shipment. A defective connection weakened due to long-term use of battery packs applied to various devices may be diagnosed.

The above-described diagnostic device and method are not limited to the embodiments described in each drawing, and the structures described in each drawing may be applied in combination. As an example, the diagnostic device and method according to the present disclosure may measure a cell impedance and a first module impedance after activation or direct current internal resistance measurement as described above. As another example, the diagnostic device and method according to the present disclosure may measure a cell impedance and a first module impedance after activation, and remeasure a cell impedance and a first module impedance after measuring direct current internal resistance.

Although aspects of the present disclosure have been described above with limited examples and drawings, the present disclosure is not limited thereto, and various implementations can be made by those skilled in the art to which the present disclosure pertains, within the scope of equivalency of the technical idea of the present disclosure and the scope of the claims described below.

### DESCRIPTION OF REFERENCE NUMERALS

100: Diagnostic device
120: Measurement unit
121: Cell measurement unit
122: Module measurement unit
130: control unit
131: Calculation unit
132: Determination unit

1. A diagnostic device for inspecting an assembly state of a battery module including at least one component and a plurality of battery cells, the diagnostic device comprising:
a measurement unit which measures cell impedances of the plurality of battery cells, a fixed impedance of the at least one component, and a first module impedance of the battery module; and
a control unit which determines an assembly state of the battery module based on the cell impedances, the fixed impedance, and the first module impedance.

2. The diagnostic device of claim 1, wherein the control unit calculates a second module impedance by determining a sum of the cell impedances and adding the fixed impedance to the sum, and compares the first module impedance and the second module impedance to determine the assembly state of the battery module.

3. The diagnostic device of claim 2, wherein the control unit determines that the assembly state of the battery module is acceptable if a difference between the first module impedance and the second module impedance is within a threshold, and determines that the assembly state of the battery module is defective if the difference between the first module impedance and the second module impedance exceeds the threshold.

4. The diagnostic device of claim 2, wherein the measurement unit comprises:
a cell measurement unit which measures the respective cell impedances for the plurality of battery cells; and
a module measurement unit which measures the first module impedance of the battery module.

5. The diagnostic device of claim 4, wherein the module measurement unit has a higher measurable voltage range than the cell measurement unit.

6. The diagnostic device of claim 4, wherein the module measurement unit has the same measurable voltage range as the cell measurement unit.

7. The diagnostic device of claim 6, wherein the diagnostic device further comprises a voltage distribution circuit which electrically connects the module measurement unit and the battery module and which includes a plurality of resistors.

8. The diagnostic device of claim 7, wherein the voltage distribution circuit distributes a voltage input from the battery module according to a resistance ratio of the plurality of resistors and supplies a generated module voltage to the module measurement unit.

9. The diagnostic device of claim 1, wherein the diagnostic device further comprises a memory in which the fixed impedance is stored, wherein the first module impedance and the cell impedances change based on variations in a frequency, and the fixed impedance has a fixed value that does not change based on the variations in the frequency.

10. The diagnostic device of claim 4, wherein the cell measurement unit initially charges and activates the plurality of battery cells, and subsequently measures the cell impedances at a first time point after a first time period has elapsed, and the module measurement unit, after the activation, measures the first module impedance at a second time point after a second time period has elapsed.

11. The diagnostic device of claim 4, wherein the cell measurement unit measures a direct current internal resistance (DCIR) of the plurality of battery modules, and subsequently measures the cell impedances at a first time point after a first time period has elapsed, and the module measurement unit, after measuring the DCIR, measures the first module impedance at a second time point after a second time period has elapsed.

12. The diagnostic device of claim 10, wherein the first time period is the same the second time period.

13. A diagnostic method for diagnosing an assembly state of a battery module including at least one component and a plurality of battery cells, the method comprising:
measuring cell impedances of the plurality of battery cells, a fixed impedance of the at least one component, and a first module impedance of the battery module; and
determining an assembly state of the battery module based on the cell impedances, the fixed impedance, and the first module impedance.

14. The diagnostic device of claim 11, wherein the first time period is the same as the second time period.
